(19) United States
(12) Patent Application Publication
(10) Pub. No.: US 2025/0167784 A1
(43) Pub. Date: May 22, 2025

(54) HIGH-VOLTAGE SWITCH WITH WIRELESS CONTROL

(71) Applicant: Spellman High-Voltage Electronics Corporation, Hauppauge, NY (US)

(72) Inventors: Alexander Pokryvailo, Hauppauge, NY (US); Costel Carp, Hauppauge, NY (US); Richard MacArthur, Hauppauge, NY (US)

(21) Appl. No.: 18/514,979

(22) Filed: Nov. 20, 2023

(51) Int. Cl. H03K 17/687

(52) U.S. Cl. CPC H03K 17/6874; H01F 27/2804; H02J 50/402

(57) ABSTRACT

A high-voltage switch includes a plurality of individual receiver modules that are connected in series (i.e., daisy-chained) and driven by a wireless control device. The wireless control device includes transmitter coils and receiver coils. The transmitter coils and receiver coils can be printed on a transmitter and a receiver circuit board, respectively. The receiver coils are powered inductively by the transmitter coils. Optionally, a receiver coil can be powered inductively by at least a pair of transmitter coils that are laterally offset. In this case, the pair of transmitter coils are connected in phase or in phase opposition in such a way that their magnetic fields reinforce each other at the receiver coil. For example, the transmitter coils are spatially arranged in a rectangular array and the receiver coils are spatially arranged in another rectangular array parallel to the array of transmitter coils.

### CROSS-REFERENCE TO RELATED APPLICATIONS

None

### FIELD OF THE INVENTION

This disclosure relates generally to wireless control devices for use in high-voltage switches and to high-voltage switches using these wireless control devices. This disclosure relates more particularly to wireless control devices in which coils or windings are printed on circuit boards and/or transmitter coils or windings are connected in phase or in phase opposition in such a way that their magnetic fields reinforce one another at the receiver coils or windings.

### BACKGROUND OF THE INVENTION

High-voltage switches are known for general use, and specifically, for x-ray Dual Energy Computed Tomography (DECT).

FIG. 1 shows a known high-voltage switch disclosed in German patent no. DE 36 30 775 C2 to Behlke. In the switch according to FIG. 1, at least three power MOSFETs T1, T2, T3 are connected in series, with the drain connection D of the preceding MOSFET being connected to the source connection S of the following MOSFET. The MOSFET T1, T2, T3 are each controlled by their own ferrite ring core pulse transformer ÜA, the secondary circuits WS which are connected between the control connections G and the source connections S of the corresponding MOSFET, in such a way that the start of the secondary circuit is at the source connection S. The secondary circuits WS consist of one or two turns without any special insulation, since this is already provided by the spatial separation of the toroidal cores K and the special design of the primary circuits Wp. The primary circuits Wp are in series and are formed by a single, continuously insulated line LA for high-voltage, which is routed through all the ring cores K of the pulse transformer ÜA. The cable LA is preferably Teflon insulated, which means that several tens of kilovolts of insulation voltage can easily be achieved with an external cable diameter of just a few millimeters. The beginning of the line LA, i.e., the beginning of the first primary circuit Wp, is electrically connected to the drain connection D of a driver MOSFET TA, which has its control connection G on an input terminal EA and its source connection S on ground. The end of the line LA is connected to the terminal of an auxiliary voltage source UH, which supplies a positive voltage.

The shortcomings of the high-voltage switch shown in FIG. 1 and many similar devices may include a high cost of manufacturing that requires extensive manual work, and growing insulation problems when extending the operating range into many tens to hundreds of kV. Of these insulation problems, at least two are notable: a) high-voltage cables used for insulation line LA become inflexible which precludes shaping the switch in convenient U-configuration; and b) the best small-diameter cables are made of Polyethylene, which requires long termination on the HV side to prevent sliding discharge along the cable surface. Both problems may result in a high-voltage switch with large dimensions. In addition, the high-voltage switch shown in FIG. 1 and many similar devices may not provide sufficient flexibility for driving the MOSFETs T1, T2, T3 because all of them are controlled through the same line LA.

Despite these advances, there is a need in the art for wireless control devices for use in high-voltage switches and to high-voltage switches using these wireless control devices. Preferably, these wireless control devices have a modular, compact design and a low manufacturing cost.

### SUMMARY

The disclosure describes a high-voltage switch comprising a plurality of individual receiver modules. The receiver modules may be connected in series. Each receiver module may include a power switch, a signal conditioning circuit, and at least one receiver coil. The power switch may include control electrodes for selectively driving current flow between power electrodes. The power switch may preferably include semi-conductor devices. For example, the power switch may include one or more field-effect transistors, in which case, the power electrodes of the power switch are the drain and source terminals and the control electrode is the gate terminal whereas the control voltage is typically applied between the gate and source. Or the power switch may include one or more insulated-gate bipolar transistors, in which case the power electrodes of the power switch are the collector and emitter terminals and the control electrode is the gate terminal. Alternatively, the power switch may include mechanical devices (e.g., micro-electronic mechanical systems), gas-discharge lamps, or vacuum circuit breakers. The control electrodes of each power switch may be connected to at least one receiver coil that may be powered inductively by at least one respective transmitter coil. The at least one transmitter coil may be coaxial with its respective at least one receiver coil. The high-voltage switch implementation with individual receiver modules may provide a great flexibility for the configuration of the high-voltage switch by allowing the modules to be connected in various ways to achieve different objectives with the same basic board layout.

In some examples, the transmitter coils and the receiver coils are mounted or printed on circuit boards. The power switches and signal conditioning circuits may also be mounted on printed circuit boards. The printed circuit boards may be multi-layered, in which case several coils can overlay each other on a printed circuit board, owing to the magnetic field generated by a coil being only slightly attenuated by other coils. The use of printed circuit boards may reduce manufacturing costs. Furthermore, when printed on a board structure, the transmitter or the receiver coils form planar or quasi-planar structures that could generate relatively uniform electric fields. This electric field uniformity may allow for smaller spacings between components for any given insulation type.

In some examples, the transmitter coils and receiver coils may be spatially arranged in rectangular arrays. The arrays of coils may be planar, faceted, or curved. The transmitter coils are connected in phase or in phase opposition in such a way that their magnetic fields reinforce one another at the receiver coils. This more efficient coupling may permit a more compact design of the wireless control device.

In some examples, all the transmitter coils may be carried in one plane, and all the receiver coils may be carried in another plane parallel to the plane carrying the transmitter coils.

In some examples, the array of transmitter coils may be located between two arrays of receiver coils.

In some examples, the array of transmitter coils and the array of receiver coils may be bent or curved to a desired shape, for instance, to create a 90 deg angle.

In some examples, the transmitter coils that are adjacent in the same line or the same column in the array are connected in phase opposition and the transmitter coils that are adjacent in the same diagonal are connected in phase.

In some examples, multiple transmitter coils may form a transmitter wiring and/or multiple receiver coils may form a receiver wiring. The transmitter coils, whether overlaid or not, can be connected in parallel, series, or mixed, to a power source. The receiver coils, whether overlaid or not, can be connected in parallel, series, or mixed, to each power switch, or can individually drive one power switch.

In some examples, the high-voltage switch may be configured for on-off control. In other examples, the high-voltage switch may be configured for linear control.

The benefits of the high-voltage switch may include an absence of closed magnetic cores, hence the easiness of high-voltage isolation of the primary (grounded) driver and switch itself, a good manufacturability, and a low cost.

### BRIEF DESCRIPTION OF THE DRAWINGS

For a more detailed description of the embodiments of the disclosure, reference will now be made to the accompanying drawings, wherein:

FIG. 1 is a schematic of a known high-voltage switch;

FIG. 2 is a top view of a transmitter circuit board including an array of transmitter coils printed on it;

FIG. 3A is a top view of a receiver circuit board providing an array of receiver modules, including coils printed on the receiver circuit board, power switches mounted on the receiver circuit board and their signal conditioning circuits;

FIG. 3B is a bottom view of the receiver circuit board shown in FIG. 3A, providing another array of receiver modules;

FIG. 4 is a side sectional view of one transmitter circuit board as shown in FIG. 2 and one receiver circuit board as shown in FIGS. 3A and 3B illustrating lines of the magnetic field when in use;

FIG. 5 is a side sectional view of one transmitter circuit board as shown in FIG. 2 and two receiver circuit boards as shown in FIGS. 3A and 3B illustrating lines of the magnetic field when in use;

FIG. 6 is a side sectional view of two transmitter circuit boards as shown in FIG. 2 and one receiver circuit board as shown in FIGS. 3A and 3B illustrating lines of the magnetic field when in use;

FIG. 7 is a side sectional view of several transmitter circuit boards similar to FIG. 2 and several receiver circuit boards similar to FIGS. 3A and 3B illustrating lines of the magnetic field when in use;

FIG. 8 is a top view of a circuit board including an array of transmitter/receiver coils mounted or printed on it illustrating directions of current;

FIG. 9 is a top view of another circuit board including an array of transmitter/receiver coils mounted or printed on it illustrating directions of current;

FIG. 10 is a top view of yet another circuit board including an array of transmitter/receiver coils mounted or printed on it illustrating directions of current;

FIG. 11 is a block diagram of a receiver module;

FIG. 12A is a schematic of a power source for driving multiple transmitter coils or multiple transmitter wirings on-off;

FIG. 12B is a schematic of a power source for driving multiple transmitter coils or multiple transmitter wirings linearly;

FIGS. 13A-13C are schematics of example receiver modules that can be controlled on-off by a receiver coil or multiple receiver coils forming a receiver wiring;

FIGS. 13D-13F are schematics of example receiver modules that can be controlled linearly by a receiver coil or multiple receiver coils forming a receiver wiring; and

FIG. 14 is an example of a high-voltage switch illustration the configuration flexibility of the wireless control device in accordance with this disclosure.

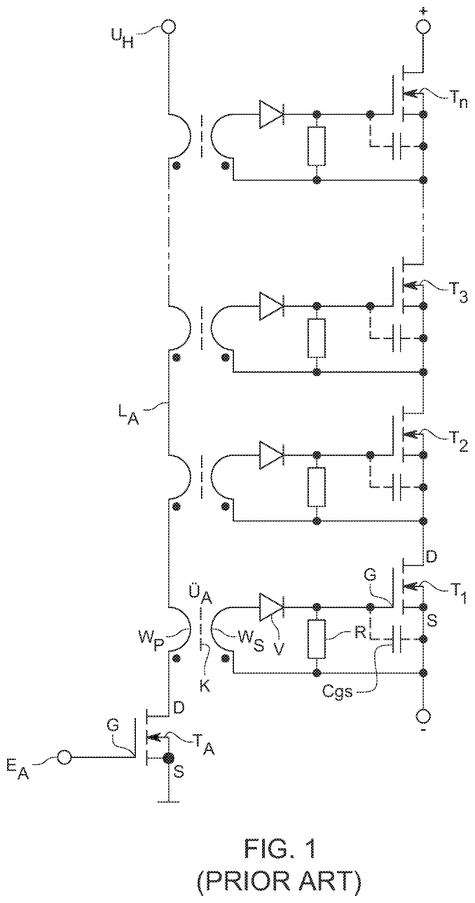

### DETAILED DESCRIPTION

The invention is susceptible to various modifications and alternative forms, and specific embodiments thereof are shown by way of example in the drawings and description. It should be understood, however, that the drawings and description are not intended to limit the invention to the particular form disclosed, but on the contrary, the intention is to cover all modifications, equivalents, and alternatives available to a person having ordinary skill in the art.

The disclosure describes preferred embodiments of wireless control devices for transferring power wirelessly, namely, by inductive power transfer (IPT), for the control of semiconductors, e.g., field-effect transistors (FETs) or insulated-gate bipolar transistors (IGBTs). These devices are typically used in high-voltage switches.

For example, the wireless control devices may comprise an array of transmitter coils (TCs) and an array of receiver coils (RCs), both printed in a planar arrangement on a printed circuit board (PCB). Pairs of laterally adjacent TCs are wired so that the current turns clockwise in one of the pair of TCs and counterclockwise in the other of the pair of TCs (i.e., they are phase-shifted by 180 deg or in phase opposition) and their magnetic fields at the front or the back of any one of the pair of adjacent TCs, where the RCs are located, are in phase. Optionally, pairs of laterally adjacent RCs may be wired so that the current turns clockwise in one of the pair of RCs and counterclockwise in the other of the pair of RCs. This geometry and wiring of the coils may provide a more efficient coupling between the TCs and the RCs via the magnetic field. This more efficient coupling may, in turn, permit a more compact design of the wireless control device. Furthermore, when printed on a board structure, the TCs and RCs form planar or quasi-planar structures that may generate relatively uniform electric fields. This electric field uniformity may allow for smaller spacings between components for any given insulation type. These smaller spacing may again permit a more compact design of the wireless control device.

Alternatively, by using several PCBs judiciously angled, it is possible to create many desired switch geometries that are not planar. Also, if flexible PCBs are used, curved configurations are possible, e.g., a coaxial cylinder with the RCs arranged on the inner cylinder, and the TCs arranged on the outer cylinder, or vice versa.

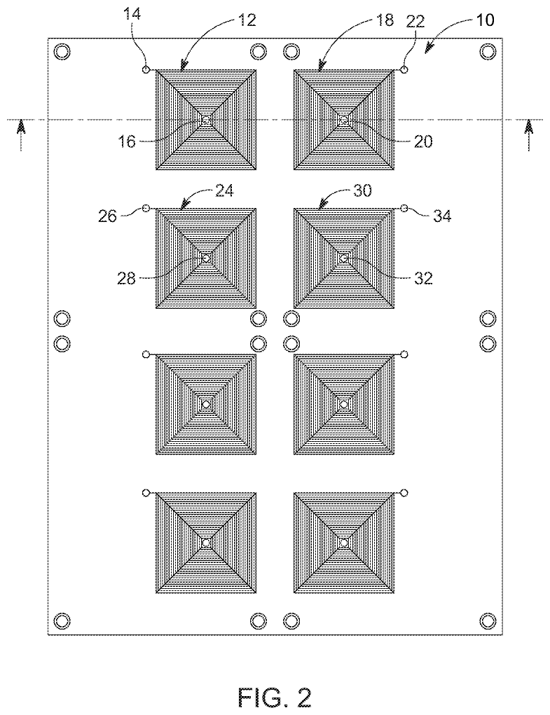

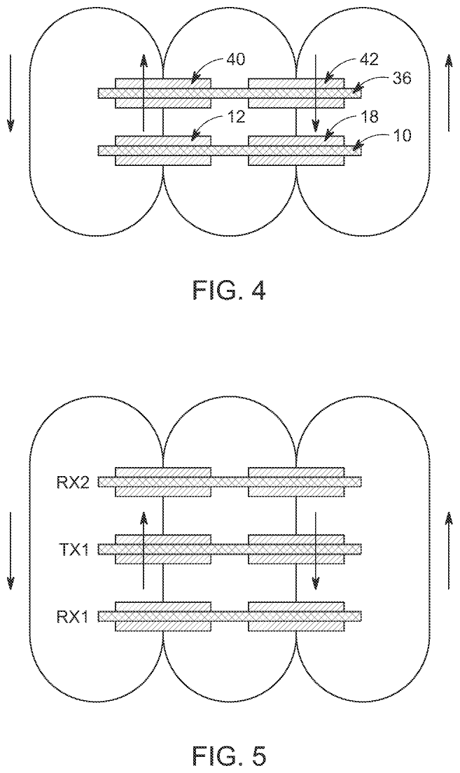

FIG. 2 shows a transmitter board 10. In this preferred embodiment, an array of two columns and four rows of TCs is shown printed on the top face of the transmitter board. The TCs are all rectangular spiral coils. The coils in the first column are identical. The coils in the second column are mirror images of the coils in the first column. For example, coils 12 and 18 are in the same row, coils 12 and 24 are in the same column, and coils 12 and 30 are in the same diagonal. Coils 12, 18, 24, and 30 each have a first electrode 14, 20, 26, and 32, respectively, and a second electrode 16, 22, 28, and 34, respectively. When a current flows from the first electrode 14, 20, 26, or 32 to the second electrode 16, 22, 28, or 34, respectively, the current is turning counterclockwise, and a magnetic field coming out of the page is generated inside the coil, and going into the page around the coil, as is shown, for example, on the left of FIG. 4. Conversely, a current flowing in the clockwise direction would generate a magnetic field going into the page inside the coil, and coming out of the page around the coil, as is shown, for example, on the right of FIG. 4.

In use, coils 12 and 18, which are located on the same line of the array, would be either coupled in series, such as by connecting the second electrode 16 to the second electrode 22, or coupled in parallel by connecting the second electrode 16 to the first electrode 20. Either way, the current flowing through the coil 12 from the first electrode 14 to the second electrode 16, and the current flowing through the coil 18 from the first electrode 20 to the second electrode 22 will be in phase opposition.

Similarly, coils 12 and 24, which are located on the same column of the array, would be either coupled in series, such as by connecting the second electrode 16 to the second electrode 28, or coupled in parallel by connecting the second electrode 16 to the first electrode 26. Again, the current flowing through the coil 12 from the first electrode 14 to the second electrode 16, and the current flowing through the coil 24 from the first electrode 26 to the second electrode 28 will be in phase opposition. In contrast, coils 12 and 30, which are located on a diagonal of the array, would be either coupled in series, such as by connecting the second electrode 16 to the first electrode 32, or coupled in parallel by connecting the second electrode 16 to the second electrode 34 so that, the current flowing through the coil 12 from the first electrode 14 to the second electrode 16, and the current flowing through the coil 30 from the first electrode 32 to the second electrode 34 will instead be in phase.

The other four coils shown at the bottom of the transmitter board 10 may be similar to the coils 12, 18, 24, and 30.

In some preferred embodiments, an array of two columns and four rows of TCs may also be printed on the bottom face of the transmitter board. The array printed at the bottom of the transmitter board may be like the array shown in FIG. 2. In this case, two overlaid coils are preferably connected in series, for example by connecting the central electrode (i.e., the second electrode 16) of the top coil to the central electrode (i.e., also the second electrode 16) of the bottom coil. By doing so, the magnetic fields of both electrodes are almost identical and reinforce each other. The set of the top and bottom overlaid coils will be referred to as a winding. Alternatively, the array printed at the bottom of the transmitter board may be like the array shown in FIG. 2 with the first and second columns switched. In this case, two overlaid coils are preferably connected in parallel.

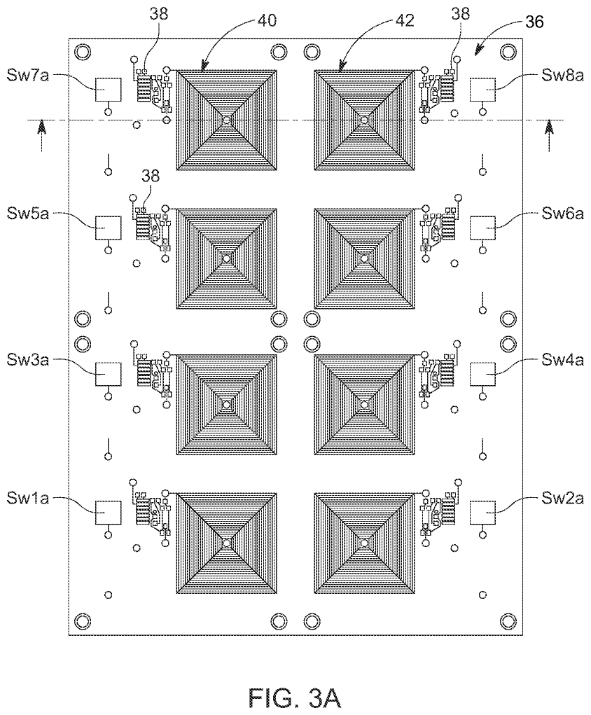

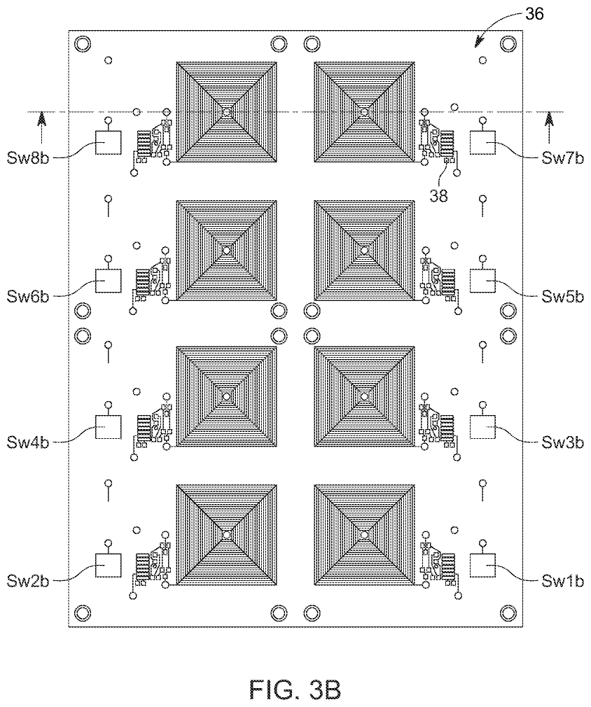

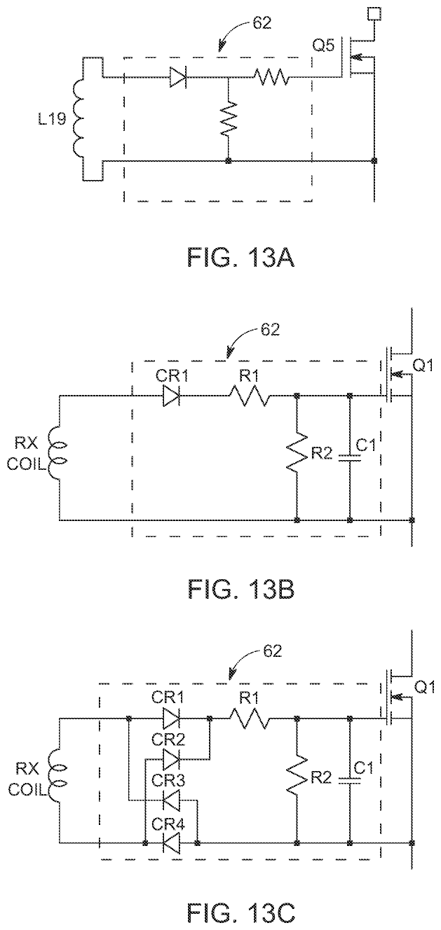

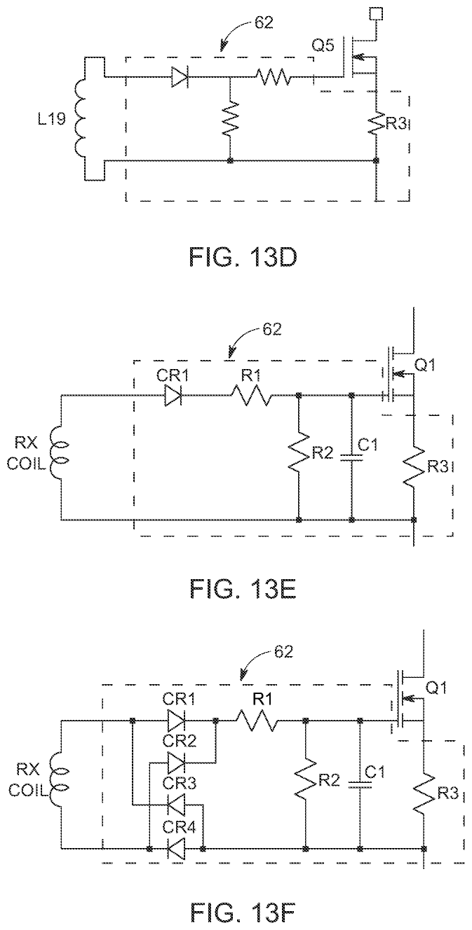

FIG. 3A shows a top side of a receiver board 36. In this preferred embodiment, an array of two columns and four rows of RCs is shown printed on the top face of the receiver board 36. The RCs are all rectangular spiral coils. The receiver board 36 differs from the transmitter board 10 in that it includes tracks, such as shown at 38, onto which the components of a signal conditioning circuit (such as exemplified in FIGS. 13A-13F) can be mounted. In use, each RC of the array is connected to the control electrodes of one of the eight power switches Swla-Sw8a. When the signal conditioning circuits include a rectifier, which electrode of the RC is connected to which electrode of the power switch may not matter.

In some preferred embodiments, an array of two columns and four rows of RCs may also be printed on the bottom face of the receiver board 36, as is shown in FIG. 3B. However, in other preferred embodiments, the two columns (or the four rows) can be split on two receiver boards to provide adequate insulation by removing creepage along PCB. Furthermore, fewer than two (i.e., one) or more than two columns and/or fewer than four or more than four rows can be used for the high voltage switch construction.

The tracks 38 may also be printed on the bottom face of the receiver board 36. In this case, each RC of the array printed on the bottom face is again connected to the control electrodes of one of the eight power switches Sw1b-Sw8b. Thus, the receiver board 36 may provide sixteen power switches. Any pair of power switches overlayed on the top and bottom faces of the receiver board 36, e.g., Sw1a and Sw1b, are preferably connected in series. Then, Sw1b can be connected in series to Sw2b, Sw2a to Sw4a, Sw4b to Sw3b, Sw3a to Sw5a, Sw5b to Sw6b, Sw6a to Sw8a, and Sw8b to Sw7b. In this configuration, the high-voltage switch utilizes all the PCB length, which facilitates mechanical packaging in long structures when the input and output of the high-voltage switch are desired to be far from each other. Alternatively, in another preferred embodiment, all switches of one column are connected in series (Swla to Sw1b to Sw3b to Sw3a, etc., ending by Sw7a for the left column of FIG. 3b, and Sw8a to Sw8b to Sw6b to Sw6a, etc., ending by Swla for the right column of FIG. 3b). Then, Sw7a is connected to Sw8a. This configuration may be convenient when the input and output of the high-voltage switch are desired to be close to each other. Such a configuration can also decrease parasitic inductance.

Alternatively, the tracks 38 may not be printed on the bottom face of the receiver board. In this case, each RC of the array printed on the bottom face is coupled in series or in parallel to an overlaid RC printed on the top face of the receiver board and ultimately to one of the eight power switches Sw1a-Sw8a printed on the top face of the receiver board. Thus, the receiver board 36 may provide only eight power switches coupled to sixteen RCs. Again, the set of the top and bottom overlaid coils will be referred to as a winding. A winding including two coils that are coupled in series would generate a higher induced voltage. A winding including two coils that are coupled in parallel would have a lower inductance, which may shorten the time to turn the power switches on and off.

FIG. 4 illustrates where, in use, the RCs of the receiver board 36, in particular RCs 40 and 42, are located relative the magnetic field of the TCs, in particular TCs 12 and 18, of the transmitter board 10. The RC 40 (and/or the winding it is part of) is located in a portion of space where the magnetic field generated by the TC 12 (and/or the winding it is part of) is substantially uniform and pointing substantially up and the magnetic field generated by the TC 18 (and/or the winding it is part of) is substantially uniform and pointing substantially down when the TCs 12 and 18 are independently driven in phase (e.g., the current is flowing counterclockwise in FIG. 2A). However, since in use the TCs 12 and 18 are coupled in phase opposition, the magnetic fields generated by the TCs 12 and 18 reinforce each other at the RC 40. The RC 42 (and/or the winding it is part of) is preferably located in another portion of space where the magnetic field generated by the TC 12 (and/or the winding it is part of) is substantially uniform and pointing substantially down and the magnetic field generated by the TC 18 (and/or the winding it is part of) is also substantially uniform and pointing substantially up when the TCs 12 and 18 are independently driven in phase. Again, since in use the TCs 12 and 18 are coupled in phase opposition, the magnetic fields generated by the TCs 12 and 18 reinforce each other at the RC 42.

In the preferred embodiment shown in FIG. 4, the transmitter board 10 is parallel to the receiver board 36, but it could be otherwise in other embodiments.

While FIG. 4 only illustrate TCs 12 and 18, and RCs 40 and 42, the configuration of any two adjacent TCs and RCs in a line or a column of the arrays shown in FIGS. 2, 3A and 3B would be similar to FIG. 4, with sometimes the inversion of the magnetic field.

FIG. 5 shows a preferred embodiment of a wireless control device where a transmitter board TX1 is located between two receiver boards RX1 and RX2 and is capable of powering the two receiver boards. While this preferred embodiment shows the transmitter board TX1 at the middle point between two receiver boards RX1 and RX2, it could be otherwise in other embodiments.

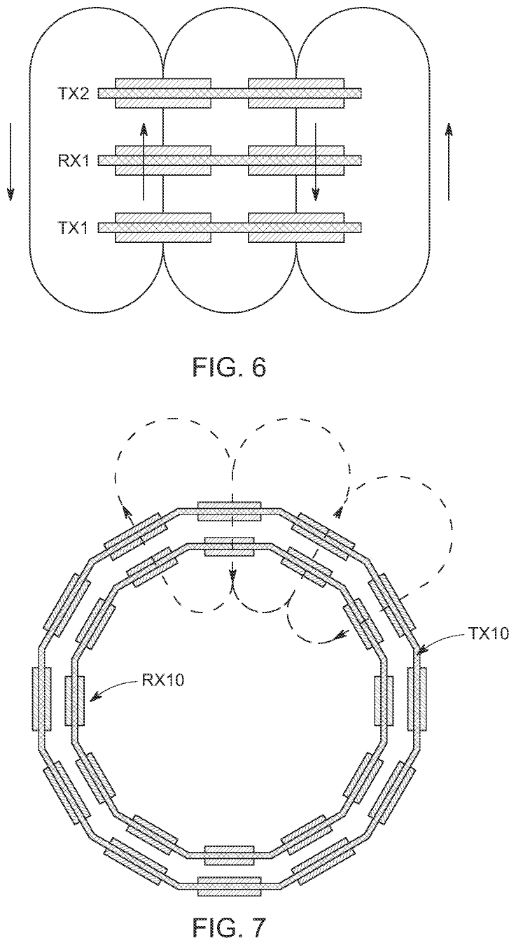

FIG. 6 shows a preferred embodiment of a wireless control device where a receiver board RX1 is located between two transmitter boards TX1 and TX2 that cooperate to power the receiver board. While this preferred embodiment shows the receiver board RX1 at the middle point between two receiver boards TX1 and TX2, it could be otherwise in other embodiments.

FIG. 7 shows a preferred embodiment of a wireless control device where the transmitter board TX10 and the receiver board RX10 are formed with a plurality of flat, unitary boards, which are parallel to one another. The transmitter board TX10 and the receiver board RX10 have an overall geometry that is polygonal. Like in preceding embodiments, the rectangular spiral coils may be printed on both faces of the transmitter board TX10 and the receiver board RX10. In this preferred embodiment, the arrays of coils have twelve rows arranged in a dodecagon, and any number of columns arranged along the central axis of the dodecagon.

FIG. 8 shows a preferred embodiment of a transmitter board 44 including an array of coils and/or wirings that are coupled in series, parallel, or mixed. For example, the coils may include solenoids. In a plurality of coils and/or wirings 46, the current runs counterclockwise when a positive voltage is applied. In another plurality of coils and/or wirings 48, the current runs clockwise when a positive voltage is applied. The coils and/or wirings 46 are arranged in a checkerboard pattern about the transmitter board 44, and each of the coils and/or wirings 48 is located between two TCs and/or windings 48 adjacent in a line or in a column of the checkerboard pattern. The transmitter board 44 can be used with a receiver board having a similar design to form a wireless control device.

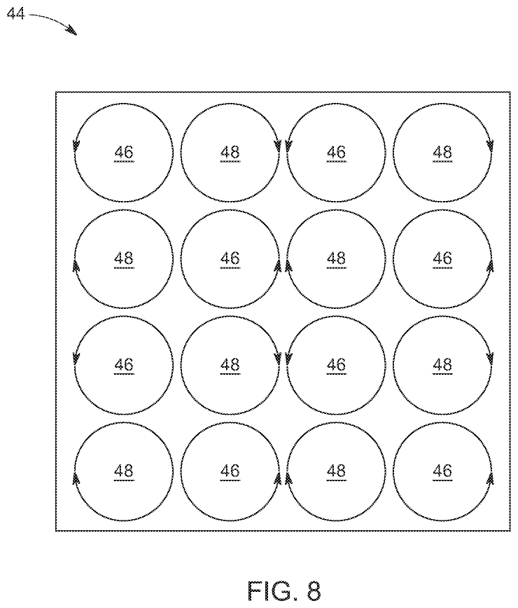

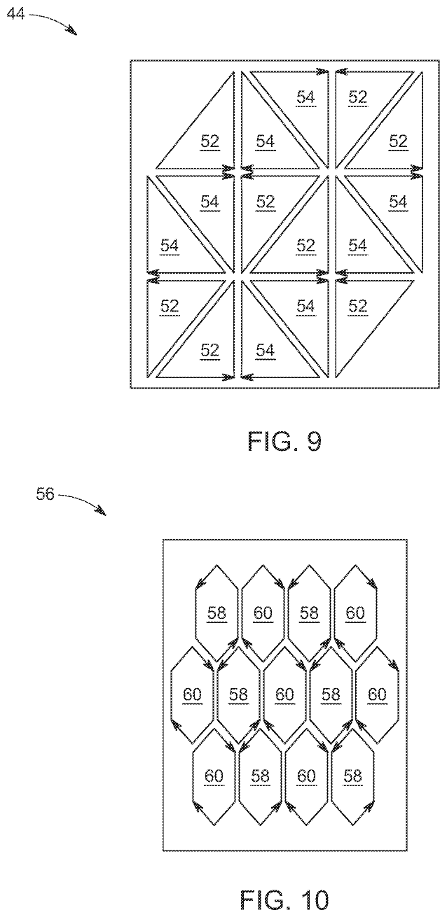

FIG. 9 shows a preferred embodiment of a transmitter board 50 including an array of coils and/or wirings that are coupled in series, parallel, or mixed. In this preferred embodiment, the coils and/or wirings are right angle triangles. In a plurality of coils and/or wirings 52, the current runs counterclockwise when a positive voltage is applied. In another plurality of coils and/or wirings 54, the current runs clockwise when a positive voltage is applied. Each coil and/or wiring is adjacent to at least one and sometimes two, coil(s) and/or wiring(s), in which the current would flow in phase opposition. The transmitter board 50 can also be used with a receiver board having a similar design to form a wireless control device.

FIG. 10 shows a preferred embodiment of a transmitter board 56 including an array of coils and/or wirings that are coupled in series, parallel, or mixed. In this preferred embodiment, the coils and/or wirings are hexagonal. In a plurality of coils and/or wirings 58, the current runs counterclockwise when a positive voltage is applied. In another plurality of coils and/or wirings 60, the current runs clockwise when a positive voltage is applied. The transmitter board 56 can also be used with a receiver board having a similar design to form a wireless control device.

While the preferred embodiments have illustrated rectangular (or square), circular, triangular, and hexagonal coils and/or wirings, the shape of the coils and/or wirings could be different in other embodiments.

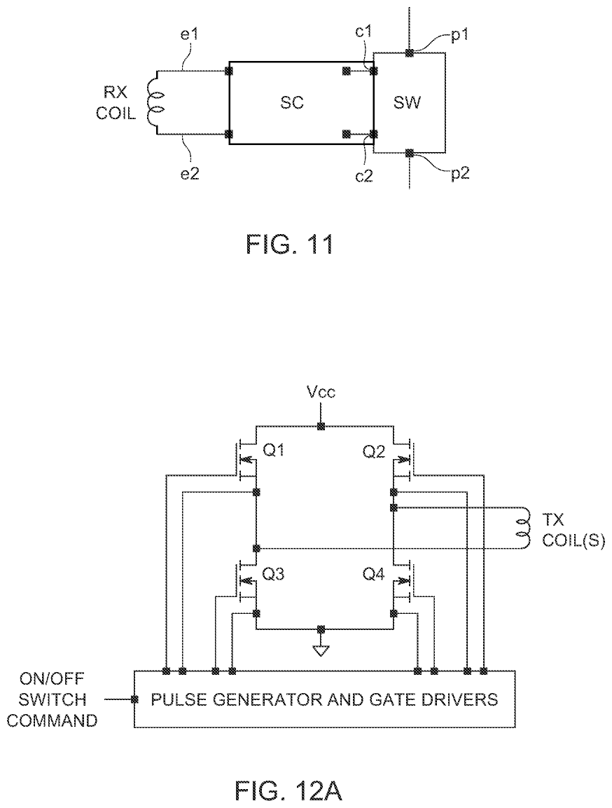

The block diagram of FIG. 11 shows a receiver module in accordance with the disclosure. The receiver module includes a power switch SW and a receiver winding RX COIL around a direction.

The power switch SW has control electrodes c1 and c2 for selectively driving current flow between power electrodes p1 and p2. In general, the power switch SC could be based on a semi-conductor, mechanical, gas-discharge device, etc. In the preferred cases where a semi-conductor (e.g., SCRs, FETs, IGBTs) is used, one control electrode may be connected to a gate terminal and the other electrode may be connected to one of the power electrodes.

The receiver winding RX COIL has first and second electrodes e1 and e2. The first and second electrodes e1 and e2 are connected to the control electrodes c1 and c2 via a signal conditioning circuit SC. Generally, the signal conditioning circuit SC is a network comprising one or more diodes, capacitors, resistors, etc. The signal conditioner preferably includes a rectifier (i.e., one or more diodes), but capacitors or resistors are optional.

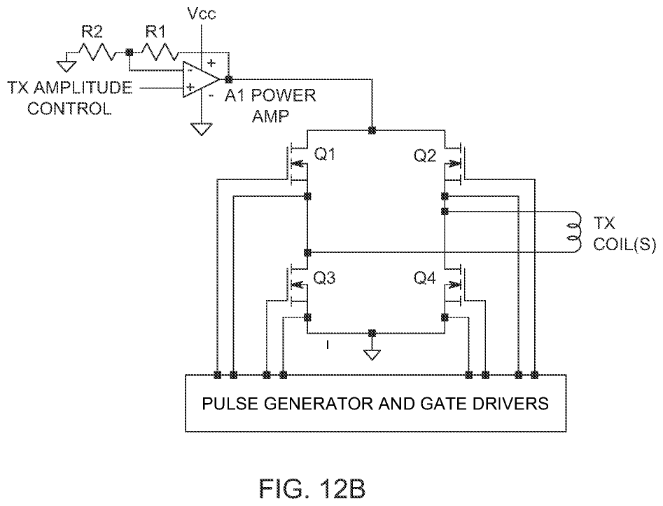

In some preferred embodiments, the receiver winding RX COIL would power and drive the power switch SW either full ON or full OFF. However, in other embodiments, the power switch SW may be operated in a linear mode, somewhere between full ON and full OFF. For the sake of completeness, FIGS. 12A and 12B illustrate examples of preferred embodiment of a power source for driving multiple TCs or multiple transmitter wirings coupled in series or in parallel (or in a mix of series and parallel) suitable for driving the power switches ON/OFF and linearly, respectively. However, any known or future developed power source may be used in other embodiments. FIG. 12A shows a chopper operating from a fixed voltage Vcc, which could be used in combination with the receiver modules shown in FIG. 13A, 13B, or 13C. Instead, FIG. 12B shows a variable amplitude power amplifier capable of controlling, for example, a FET's gate-to-sense voltage. The power amplifier voltage controls the current amplitude at the TCs, and thus the voltage amplitude at the RCs and the resulting control signal at the control electrodes. The power amplifier shown in FIG. 12 B could be used in combination with the receiver modules shown in FIG. 13D, 13E, or 13F.

Again, for the sake of completeness, FIGS. 13A-13F illustrate example schematics of receiver modules. However, any known or future developed receiver module may be used with the wireless control devices described herein. Each receiver module includes a signal conditioning circuit which preferably comprises a rectifier. In the example shown, the power switch includes a single transistor. However, several transistor components coupled in parallel could be used in other embodiments. The receiver modules shown in FIGS. 13A-13C are suitable for driving the power switches either full ON or full OFF. However, the disclosure is not limited to such driving of the power switches. Indeed, the receiver modules shown in FIGS. 13D-13F are suitable for driving the power switches linearly anywhere between full ON and full OFF. For this linear drive, the signal conditioning circuit may be similarly arranged with at least a diode for peak detection. Compared to the receiver modules shown in FIGS. 13A-13C, a degeneration resistor R3 is added in the source to help linearize or stabilize the FET gain.

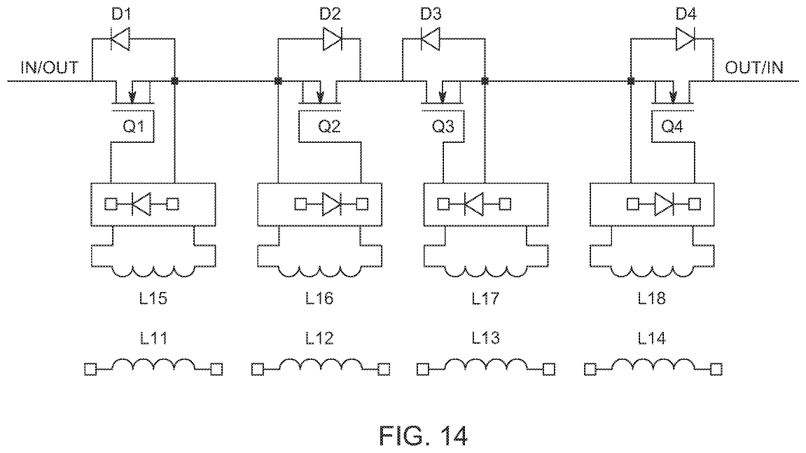

The schematic of FIG. 14 shows four receiver modules connected in series (i.e., daisy-chained). FET Q1 and diode D1, FET Q2 and diode D2, FET Q3 and diode D3, and FET Q4 and diode D4, represent bi-directional (AC capable) power switches. The diodes antiparallel to FETs are usually intrinsic ones. When L11, L13 are energized, the current can flow from the left to the right via Q1-D2-Q3-D4. When L12, L14 are energized the current can flow from the right to the left. Signal conditioning circuits including a rectifier are shown schematically to indicate that the control electrodes (gate terminals) are driven by a positive voltage.

FIG. 14 depicts a bidirectional high-voltage switch illustrating the configuration flexibility of the wireless control device in accordance with this disclosure. Indeed, TCs L11-L14 can be printed on one PCB having a basic layout identical to the one shown in FIG. 2 (only one column needed), and RCs L15-L18 can be on another PCB having a basic layout identical to the one shown in FIG. 3A (again, only one column needed). Thus, PCBs with the same basic board layout can be mass-produced and wired in various ways to achieve different objectives. In addition to the foregoing, the disclosure also contemplates at least the following embodiments 1-21. It should be noted that any element of any of these embodiments may further include details related to this element that are disclosed in a paragraph or Figure describing the preferred embodiments without including details of other elements that are disclosed in the same or other paragraph or Figure.

### Embodiment 1

Embodiment 1 is a wireless control for a high-voltage switch. Typically, the high-voltage switch includes one or more first receiver modules and, optionally, one or more second receiver modules; each of the one or more first receiver modules and, if included, each of the one or more second receiver modules includes a power switch that has control electrodes for selectively driving current flow between its power electrodes. The power electrodes of each power switch of the one or more first receiver modules and, if included, the power electrodes of the each power switch of the one or more second receiver modules are typically connected in series, or daisy-chained.

The wireless control comprises a first transmitter winding around a direction including first and second electrodes, and, optionally, a second transmitter winding around a direction also including first and second electrodes. If included, a center of the second transmitter winding is located away from a center of first transmitter winding and sideways from the direction of first transmitter winding. The first and second electrodes of the first receiver winding are connectable to the control electrodes of the one first receiver module, and, if included, the first and second control electrodes of the second receiver winding are connectable to the control electrodes of the one second receiver module.

The wireless control comprises a first receiver winding around a direction including first and second electrodes. Generally, the first receiver winding is preferably located in a first portion of space where the magnetic field generated by the first transmitter winding is substantially uniform and pointing substantially in one direction (e.g., a positive direction) and the magnetic field generated by the second transmitter winding, if included, is substantially uniform and pointing substantially in the direction opposite (e.g., a negative direction) of the direction of the magnetic field generated by the first transmitter winding when the first and second transmitter winding are independently driven in phase. More particularly, the first receiver winding may be located relative to the first transmitter winding and the second transmitter winding so that a first voltage inducted by the first transmitter winding between the first and the second electrodes of the first receiver winding when a first driving current flows through the first transmitter winding from its first electrode to its second electrode, and a second voltage inducted by the second transmitter winding between the first and the second electrodes of the first receiver winding when a second driving current flows through the second transmitter winding from its first electrode to its second electrode, are in phase opposition when the first driving current and the second driving current are in phase. However, the first and second voltages may or may not have the same magnitude, depending on the characteristics and positions of the windings.

The wireless control further may optionally comprise a second receiver winding around a direction including first and second electrodes. If included, a center of the second receiver winding is located away from a center of the first receiver winding and sideways from the direction of first receiver winding. Generally, the second receiver winding is preferably located in a second portion of space where the magnetic field generated by the first transmitter winding is substantially uniform and pointing substantially in the direction opposite (e.g., a negative direction) of its direction in the first portion of space and the magnetic field generated by the second transmitter winding is also substantially uniform and pointing substantially in the direction opposite (e.g., a positive direction) of its direction in the first portion of space. More particularly, the second receiver winding is located relative to the first transmitter winding so that a third voltage inducted by the first transmitter winding between the first and the second electrodes of the second receiver winding when the first driving current flows through the first transmitter winding from its first electrode to its second electrode, and the first voltage, are in phase opposition. However, the first and third voltages may or may not have the same magnitude, depending on the characteristics and positions of the windings. Also, the second receiver winding is located relative to the second transmitter winding so that a fourth voltage inducted by the second transmitter winding between the first and the second electrodes of the second receiver winding when the second driving current flows through the second transmitter winding from its first electrode to its second electrode, and the second voltage, are in phase opposition. However, the second and fourth voltages may or may not have the same magnitude, depending on the characteristics and positions of the windings.

If the second transmitter winding is provided, either the second electrode of the first transmitter winding is connected to the second electrode of the second transmitter winding and the first transmitter winding and the second transmitter winding are coupled in series, or the second electrode of the first transmitter winding is connected to the first electrode of the second transmitter winding and the first transmitter winding and the second transmitter winding are coupled in parallel. Consequently, in use, the first driving current flowing through the first transmitter winding and the second driving current flowing through the second transmitter winding are in phase opposition. However, when driven in parallel, the first driving current and the second driving current may or may not have the same magnitude depending on the characteristics of the transmitter windings. As such, the magnetic field generated by the first transmitter winding and the magnetic field generated by the second transmitter winding reinforce each other in the first portion of space and in the second portion of space. Thus, the voltages inducted in the first receiver winding and the second receiver winding when both the first transmitter winding and the second transmitter winding are used, can be sufficiently large to drive the one first receiver module and/or the one second receiver module, even when the sizes of the first and second transmitter windings and/or the first and second receiver windings are small. In particular, the wireless control described in embodiment 1 may be made more compact than by using other configurations of the first and second transmitter windings and/or the first and second receiver windings.

Preferably, the first and second transmitter windings have essentially similar characteristics (i.e., they are matched). Also, the first and second transmitter windings have essentially similar characteristics.

While only the first and second transmitter windings and the first and second transmitter windings have been described in detail, this embodiment can generally include more transmitter and/or receiver windings.

### Embodiment 2

Embodiment 2 is a wireless control as described in embodiment 1, wherein the first transmitter winding and, if included, the second transmitter winding is/are printed on a transmitter circuit board. This type of windings may be made very compact. Similarly, the first receiver winding and, if included, the second receiver winding are printed on a receiver circuit board. The transmitter circuit board and/or the receiver circuit board may or may not be unitary and may or may not have an overall geometry that is flat. For example, the transmitter circuit board and/or the receiver circuit board may be formed with a plurality of flat, unitary boards, and may have an overall geometry that is polygonal.

### Embodiment 3

Embodiment 3 is a wireless control as described in embodiment 2, wherein the receiver circuit board is coupled to the transmitter circuit board so that the receiver circuit board is held parallel to the transmitter circuit board. Again, the transmitter circuit board and/or the receiver circuit board may or may not be unitary and may or may not have an overall geometry that is flat. For example, each of a plurality of flat, unitary boards forming the transmitter circuit board may be parallel to one of a plurality of flat, unitary boards forming the receiver circuit board.

### Embodiment 4

Embodiment 4 is a wireless control as described in embodiments 2 or 3, wherein the transmitter circuit board and the receiver circuit board are flat.

### Embodiment 5

Embodiment 5 is a wireless control as described in any of embodiments 1 to 4, wherein the direction of the first receiver winding is aligned with the direction of the first transmitter winding (e.g., the first receiver winding and the first transmitter winding are coaxial). Furthermore, if included, the direction of the second receiver winding is aligned with the direction of the second transmitter winding (e.g., the second receiver winding and the second transmitter winding are coaxial).

### Embodiment 6

Embodiment 6 is a wireless control as described in any of embodiments 1 to 5, further comprising a third transmitter winding around a direction including first and second electrodes, and, optionally, a fourth transmitter winding around a direction including first and second electrodes. The direction of the first transmitter winding and the direction of the third transmitter winding are aligned with the direction of the first receiver winding (e.g., the first receiver winding, the first transmitter winding, and the third transmitter winding are coaxial). If included, the direction of the second transmitter winding and the direction of the fourth transmitter winding are aligned with the direction of the second receiver winding (e.g., the second receiver winding, the second transmitter winding, and the fourth transmitter winding are coaxial).

Generally, the third transmitter winding is preferably positioned so that the magnetic field generated by the first transmitter winding and the magnetic field generated by the third transmitter winding substantially reinforce each other in the first portion of space where the first receiver winding is located. Similarly, if included, the fourth transmitter winding is preferably positioned so that the magnetic field generated by the second transmitter winding and the magnetic field generated by the fourth transmitter winding substantially reinforce each other in the second portion of space where the second receiver winding is located. Also, the third transmitter winding and the fourth transmitter winding may be coupled to each other in a way similar to the way the first transmitter winding and the second transmitter winding are coupled to each other. Finally, the winding set including the third transmitter winding and, optionally, the fourth transmitter winding is coupled in series or in parallel with the winding set including the first transmitter winding and, optionally, the second transmitter winding.

More particularly, a fifth voltage inducted by the third transmitter winding between the first and the second electrodes of the first receiver winding when a third driving current flows through the third transmitter winding from its first electrode to its second electrode, and the first voltage, are in phase. Also, if included, a sixth voltage inducted by the fourth transmitter winding between the first and the second electrodes of the second receiver winding when a fourth driving current flows through the fourth transmitter winding from its first electrode to its second electrode, and the fourth voltage, are in phase. Furthermore, either the second electrode of the third transmitter winding is connected to the second electrode of the first transmitter winding and the third transmitter winding and the first transmitter are coupled in series, or the second electrode of the third transmitter winding is connected to the first electrode of the first transmitter winding and the third transmitter winding and the first transmitter are coupled in parallel. Consequently, in use, the third driving current flowing through the third transmitter winding and the first driving current flowing through the first transmitter winding are in phase.

If the second and fourth transmitter windings are included, then, in order to drive the winding set including the third transmitter winding and the fourth transmitter winding in series with the winding set including the first transmitter winding and the second transmitter winding, the first electrode of the second transmitter winding is connected to the first electrode of the third transmitter winding. In order to drive the winding set including the third transmitter winding and the fourth transmitter winding in parallel with the winding set including the first transmitter winding and the second transmitter winding, the first electrode of the second transmitter winding is connected to the first electrode of the fourth transmitter winding. As such, in use, the second driving current flowing through the second transmitter winding and the fourth driving current flowing through the fourth transmitter winding are in phase, and the fourth driving current flowing through the fourth transmitter winding and the third driving current flowing through the third transmitter winding are in phase opposition.

### Embodiment 7

Embodiment 7 is a wireless control as described in embodiment 6, wherein the third transmitter winding and the fourth transmitter winding are printed on another transmitter circuit board. Again, the other transmitter circuit board may or may not be unitary and may or may not have an overall geometry that is flat. The transmitter board and the other transmitter board are coupled in series or in parallel.

### Embodiment 8

Embodiment 8 is a wireless control as described is embodiments 6 or 7, wherein the other transmitter circuit board is coupled to the receiver circuit board so that the receiver circuit board is located between the transmitter circuit board and the other transmitter circuit board, and preferably, the other transmitter circuit board is held parallel to the receiver circuit board. For example, each of a plurality of flat, unitary boards forming the other transmitter circuit board may be parallel to one of a plurality of flat, unitary boards forming the receiver circuit board.

### Embodiment 9

Embodiment 9 is a wireless control as described is embodiment 8, wherein the receiver circuit board is located at the middle between the transmitter circuit board and the other transmitter circuit board. For example, each of a plurality of flat, unitary boards forming the receiver circuit board may be at the middle between one of a plurality of flat, unitary board forming the transmitter circuit board and one of a plurality of flat, unitary board forming the other transmitter circuit board.

### Embodiment 10

Embodiment 10 is a wireless control as described in any of embodiments 1 to 9, further comprising and third receiver winding around a direction including first and second electrodes, and, optionally, a fourth receiver winding around a direction including first and second electrodes. The first and second electrodes of the third receiver winding are connectable to the control electrodes of one of the power switch of the first receiver modules, and, if included, the first and second control electrodes of the fourth receiver winding are connectable to the control electrodes of the power switch of the one of the second receiver modules.

The first transmitter winding and the second transmitter winding are printed on a transmitter circuit board. The first receiver winding and the second receiver winding are printed on a receiver circuit board is coupled to the transmitter circuit board, preferably so that the receiver circuit board is held parallel to the transmitter circuit board. The third receiver winding and the fourth receiver winding are printed on another receiver circuit board that is coupled to the transmitter circuit board, preferably so that the other receiver circuit board is also held parallel to the transmitter circuit board. The transmitter circuit board is located between the receiver circuit board and the other receiver circuit board. As such, the windings printed on the transmitter circuit board can be used to induct voltages in at least four windings, therefore contributing to making the wireless control more compact. The circuit boards may or may not be unitary and may or may not have an overall geometry that is flat.

Generally, the third receiver winding is preferably located in a third portion of space where the magnetic field generated by the first transmitter winding is substantially uniform and pointing substantially in one direction (e.g., a negative direction) and the magnetic field generated by the second transmitter winding, if included, is substantially uniform and pointing substantially in the direction opposite (e.g., a positive direction) of the direction of the magnetic field generated by the first transmitter winding when the first and second transmitter winding are independently driven in phase. More particularly, the third receiver winding is located relative to the first transmitter winding and the second transmitter winding so that a fifth voltage inducted by the first transmitter winding between the first and the second electrodes of the third receiver winding when the first driving current flows through the first transmitter winding from its first electrode to its second electrode, and a sixth voltage inducted by the second transmitter winding between the first and the second electrodes of the third receiver winding when the second driving current flows through the second transmitter winding from its first electrode to its second electrode, are in phase opposition when the first driving current and the second driving current are in phase.

If included, the fourth receiver winding is preferably located in a fourth portion of space where the magnetic field generated by the first transmitter winding is substantially uniform and pointing substantially in the direction opposite (e.g., a positive direction) of its direction in the third portion of space and the magnetic field generated by the second transmitter winding is also substantially uniform and pointing substantially in the direction opposite (e.g., a negative direction) of its direction in the third portion of space. More particularly, the fourth receiver winding is located relative to the first transmitter winding so that a seventh voltage inducted by the first transmitter winding between the first and the second electrodes of the second receiver winding when the first driving current flows through the first transmitter winding from its first electrode to its second electrode, and the first voltage, are in phase opposition. Also, the fourth receiver winding is located relative to the second transmitter winding so that an eighth voltage inducted by the second transmitter winding between the first and the second electrodes of the second receiver winding when the second driving current flows through the second transmitter winding from its first electrode to its second electrode, and the second voltage, are in phase opposition.

### Embodiment 11

Embodiment 11 is a wireless control as described in embodiment 10, wherein the direction of the first receiver winding and the direction of the third receiver winding are aligned with the direction of the first transmitter winding (e.g., the first transmitter winding, the first receiver winding, and the third receiver winding are coaxial). Furthermore, the direction of the second receiver winding and the direction of the fourth receiver winding are aligned with the direction of the second receiver winding (e.g., the second transmitter winding, the second receiver winding, and the fourth receiver winding are coaxial).

### Embodiment 12

Embodiment 12 is a wireless control as described in embodiments 10 or 11, wherein the transmitter circuit board is located at the middle between the receiver circuit board and the other receiver circuit board. For example, each of a plurality of flat, unitary boards forming the transmitter circuit board may be at the middle between one of a plurality of flat, unitary board forming the receiver circuit board and one of a plurality of flat, unitary board forming the other receiver circuit board.

### Embodiment 13

Embodiment 13 is a wireless control as described in any of embodiments 1 to 12, wherein any or all of the transmitter windings and the receiver windings is (are) printed on one or more circuit boards and comprise(s) a top coil printed on a top face of one of the circuit board and a bottom coil printed on a bottom face of the one of the circuit boards. The top coil and the bottom coil of any or all of the transmitter windings may be driven in series or in parallel with suitable connections to ensure an additive effect of the magnetic fields generated. Similarly, the top coil and the bottom coil of any or all of the receiver windings may be coupled to one of the receiver modules in series or in parallel with suitable connections to ensure an additive effect of the total inducted voltage or current.

### Embodiment 14

Embodiment 14 is a wireless control as described in any of embodiments 1 to 13, wherein any or all of the transmitter windings and the receiver windings include(s) a spiral coil. This coil geometry may be made especially compact.

### Embodiment 15

Embodiment 15 is a wireless control as described in any of embodiments 1 to 14, wherein any or all of the transmitter windings and the receiver windings include(s) a rectangular spiral coil. An arrangement of coils having this coil geometry may be made especially compact.

### Embodiment 16

Embodiment 16 is a wireless control as described in any of embodiments 1 to 15, wherein the first transmitter winding is comprised in a first plurality of transmitter windings around corresponding directions wherein each of the first plurality of transmitter windings includes first and second electrodes, the second transmitter winding, if included, is comprised in a second plurality of transmitter windings around corresponding directions wherein each of the second plurality of transmitter windings includes first and second electrodes, the first receiver winding is comprised in a first plurality of receiver windings around corresponding directions wherein each of the first plurality of receiver windings includes a power switch having first and second electrodes, and the second receiver winding, if included, is comprised in a second plurality of receiver windings around corresponding directions wherein each of the second plurality of receiver windings includes first and second electrodes.

The first and second electrodes of each one of the first plurality of the receiver windings are connectable to the control electrodes of a power switch of one of the first receiver modules. The first and second control electrodes of each of the second plurality of receiver windings, if included, are connectable to the control electrodes of a power switch of one of the second receiver modules.

If included, the second plurality transmitter windings are preferably interspaced in the first plurality transmitter windings. More specifically, a center of each of the second plurality of transmitter windings is located away from centers of each of the first plurality of transmitter windings and sideways from the directions of each of the first plurality of transmitter windings.

If included, the second plurality receiver windings are preferably interspaced in the first plurality receiver windings. More specifically, a center of each of the second plurality of receiver windings is located away from centers of each of the first plurality of receiver windings and sideways from the directions of each of the first plurality of receiver windings.

Optionally, for any one of the first plurality of receiver windings, there is at least one of the first plurality of transmitter windings, at least one of the second plurality of transmitter windings, and at least one of the second plurality of receiver windings that form a pair of transmitter windings and a pair of receiver windings having a configuration described in embodiment 1.

### Embodiment 17

Embodiment 17 is a wireless control as described in embodiment 16, wherein each of the first plurality of transmitter windings and, if included, each of the second plurality of transmitter windings are printed on a transmitter circuit board. Additionally or alternatively, each of the first plurality of receiver windings and, if included each of the second receiver windings are printed on a receiver circuit board.

### Embodiment 18

Embodiment 18 is a wireless control as described in embodiment 17, wherein the receiver circuit board is flat and preferably unitary, and the transmitter circuit board is also flat and preferably unitary.

### Embodiment 19

Embodiment 19 is a wireless control as described in embodiments 17 or 18, wherein the first plurality of transmitter windings is arranged in a checkerboard pattern about the transmitter board, and each of the second plurality of transmitter windings is located between two adjacent transmitter windings of the first plurality of transmitter windings and in a line or in a column of the checkerboard pattern. Similarly, the first plurality of receiver windings is arranged in another checkerboard pattern about the receiver board, and each of the second plurality of receiver windings is located between two adjacent receiver windings of the first plurality of receiver windings and in a line or in a column of the other checkerboard pattern.

### Embodiment 20

Embodiment 20 is a wireless control as described in embodiment 19, wherein the transmitter windings are arranged in a rectangular array. The receiver windings are also arranged in a rectangular array. Preferably, the array of the transmitter windings and the array of the receiver windings may have the same number of lines and columns. Additionally, the arrangement of the transmitter windings and the arrangement of the receiver windings may have the same overall sizes.

### Embodiment 21

Embodiment 21 is a high-voltage switch. The high-voltage switch comprises a wireless control as described in any of embodiments 1-20. The high-voltage switch comprises one or more first receiver modules and, optionally one or more second receiver modules. Each of the one or more first receiver modules and, if included, each of the one or more second receiver modules includes a power switch that has control electrodes for selectively driving current flow between its power electrodes. The power electrodes of the power switch of the one or more first receiver modules and, if included, of the one or more second receiver modules are connected in series. The first and second electrodes of each first receiver winding are connected to the control electrodes of the power switch of the one first receiver module, and the first and second control electrodes of each second receiver winding, included, are connected to the control electrodes of the power switch of one second receiver module.

As used herein, a receiver module comprises a receiver coil, a signal conditioning circuit, and a power switch.

Typically, the signal conditioning circuit may include first and second input electrodes, first and second output electrodes, and a diode. The first and second input electrodes of the signal conditioning circuit are connected to the control electrodes of the power switch of the first receiver module or the second receiver module, respectively. The diode of the signal conditioning circuit is configured so that current is hindered from entering the signal conditioning circuit via the second output electrode, and current entering the signal conditioning circuit can flow toward the second output electrode. Optionally, the signal conditioning circuit may include more than one diode.

The signal conditioning circuit may optionally include a capacitor. The first and second input electrodes of the signal conditioning circuit are connected to the first and second output electrodes of the receiver coil, respectively. The capacitor is connected directly or indirectly between the first and second input electrodes of the signal conditioning circuit and between the first and second output electrodes of the signal conditioning circuit. Optionally, the signal conditioning circuit may also include a resistor or other component capable of discharging the capacitor.

Typically, the power switch includes first and second control electrodes, first and second power electrodes, and a transistor including a sense terminal, a gate terminal, a source/collector terminal, and a drain/emitter terminal. The first and second control electrodes of the power switch are connected to the first and second output electrodes of the signal conditioning circuit, respectively. The sense electrode and the gate terminals of the transistor are connected to the first and second control electrodes of the power switch, respectively, and the source/collector terminal and the drain/emitter terminal of the transistor are connected to the first and second power electrodes of the power switch, respectively.

Preferably, the sense electrode is at the same potential as the source electrode. However, in some cases, such as disclosed in Su-Mi Park et al., “Compact High-Voltage Pulse Discharging Switch With IGBT Stack and Simple Gate Drive Circuit,” IEEE TRANSACTIONS ON PLASMA SCIENCE, VOL. 51, NO. 7, July 2023, the sense electrode may be at the same potential as the drain electrode.

Optionally, the power switch may comprise a plurality of transistors mounted in parallel between the first and second input electrodes of the circuit, and between first and second output electrodes of the circuit. As such, the voltage rating of the circuit may be increased.

While a typical power switch has been described in embodiment 21, the power switch may alternatively include mechanical devices (e.g., micro-electronic mechanical systems), gas-discharge lamps, or vacuum circuit breakers, or equivalent.

1. A high-voltage switch, comprising:
a plurality of receiver modules, each of the plurality of receiver modules including a power switch and a receiver winding wound around a direction, each power switch having control electrodes for selectively driving current flow between power electrodes, each receiver winding having first and second electrodes, wherein, in each of the plurality of receiver modules, the first and second electrodes of the receiver winding are connected to the control electrodes of the power switch via a signal conditioning circuit,
wherein the power electrodes of the plurality of receiver modules are daisy-chained; and
a wireless control, the wireless control including a transmitter circuit board, a receiver circuit board coupled to the transmitter circuit board, and a plurality of transmitter windings wound around corresponding directions, and each receiver winding,
wherein each of the plurality of transmitter windings is printed on the transmitter circuit board,
wherein each of receiver winding is printed on the receiver circuit board.

2. The high-voltage switch of claim 1, wherein
at least one of the plurality of transmitter windings comprises a top coil printed on a top face of the transmitter circuit board and a bottom coil printed on a bottom face of the transmitter circuit board, or
at least one receiver winding comprises a top coil printed on the top face of the receiver circuit board and a bottom coil printed on the bottom face of the receiver circuit board.

3. The high-voltage switch of claim 1, wherein
at least one of the plurality of transmitter windings comprises a spiral coil, or
at least one receiver winding comprises a spiral coil.

4. The high-voltage switch of claim 3, wherein
the spiral coil of the at least one of the plurality of transmitter windings is a rectangular spiral coil, or
the spiral coil of the at least one receiver winding is a rectangular spiral coil.

5. The high-voltage switch of claim 1, wherein the receiver circuit board is held parallel to the transmitter circuit board and the direction of each receiver winding is aligned with the direction of one of the plurality of transmitter windings.

6. The high-voltage switch of claim 1, wherein the wireless control further includes:
another transmitter circuit board that is coupled to the receiver circuit board so that the receiver circuit board is located between the transmitter circuit board and the other transmitter circuit board; and
another plurality of transmitter windings wound around corresponding directions, wherein each of the other plurality of transmitter windings is printed on the other transmitter circuit board.

7. The high-voltage switch of claim 6, wherein the other transmitter circuit board is held parallel to the receiver circuit board and the direction of each receiver winding is aligned with the direction of one of the other plurality of transmitter windings.

8. The high-voltage switch of claim 6, wherein the receiver circuit board is located at the middle between the transmitter circuit board and the other transmitter circuit board.

9. The high-voltage switch of claim 1, further comprising:
another plurality of receiver modules, each of the other plurality of receiver modules including another power switch and another receiver winding wound around a direction, each other power switch having control electrodes for selectively driving current flow between power electrodes, each other receiver winding having first and second electrodes, wherein the first and second electrodes of each other receiver winding are connected to the control electrodes of one other power switch via a signal conditioning circuit,
wherein the power electrodes of the other receiver modules are daisy-chained; and
wherein the wireless control further includes another receiver circuit board that is coupled to the transmitter circuit board so that the transmitter circuit board is located between the receiver circuit board and the other receiver circuit board.

10. The high-voltage switch of claim 9, wherein the other receiver circuit board is held parallel to the transmitter circuit board and the direction of each other receiver winding is aligned with the direction of one of the plurality of transmitter windings.

11. The high-voltage switch of claim 9, wherein the transmitter circuit board is located at the middle between the receiver circuit board and the other receiver circuit board.

12. A high-voltage switch, comprising:
a first receiver module including a first power switch and a first receiver winding wound around a direction, the first power switch having control electrodes for selectively driving current flow between power electrodes, the first receiver winding having first and second electrodes, wherein the first and second electrodes of the first receiver winding are connected to the control electrodes of the first power switch; and
a second receiver module including a second power switch and a second receiver winding wound around a direction, the second power switch having control electrodes for selectively driving current flow between power electrodes, the second receiver winding having first and second electrodes, wherein the first and second control electrodes of the second receiver winding are connected to the control electrodes of the second power switch;
wherein the power electrodes of the first power switch are connected in series to the power electrodes of the second power switch; and
a wireless control, the wireless control including a first transmitter winding wound around a direction including first and second electrodes, a second transmitter winding wound around a direction including first and second electrodes, the first receiver winding, and the second receiver winding,
wherein a center of the second transmitter winding is located away from a center of the first transmitter winding and sideways from the direction of the first transmitter winding;
wherein the first receiver winding is located relative to the first transmitter winding and the second transmitter winding so that a first voltage and a second voltage are in phase opposition:
wherein the first voltage is inducted by the first transmitter winding between the first and the second electrode of the first receiver winding when a first driving current flows through the first transmitter winding from its first electrode to its second electrode, and
wherein the a second voltage is inducted by the second transmitter winding between the first and the second electrode of the first receiver winding when a second driving current flows through the second transmitter winding from its first electrode to its second electrode,
wherein the first driving current and the second driving current are in phase;
wherein a center of the second receiver winding is located away from a center of the first receiver winding and sideways from the direction of the first receiver winding;
wherein the second receiver winding is further located relative to the first transmitter winding and the second transmitter winding so that a third voltage and the first voltage are in phase opposition, and a fourth voltage and the second voltage are in phase opposition:
wherein the third voltage is inducted by the first transmitter winding between the first and the second electrode of the second receiver winding when the first driving current flows through the first transmitter winding from its first electrode to its second electrode,
wherein the fourth voltage is inducted by the second transmitter winding between the first and the second electrode of the second receiver winding when the second driving current flows through the second transmitter winding from its first electrode to its second electrode,
wherein the first transmitter winding and the second transmitter winding are coupled in series or in parallel so that, in use, the first driving current flowing through the first transmitter winding and the second driving current flowing through the second transmitter winding are in phase opposition.

13. The high-voltage switch of claim 12, wherein
the direction of the first receiver winding is aligned with the direction of the first transmitter winding; and
the direction of the second receiver winding is aligned with the direction of the second transmitter winding.

14. The high-voltage switch of claim 13, further comprising:
a third transmitter winding wound around a direction including first and second electrodes, wherein the direction of the third transmitter winding is aligned with the direction of the first receiver winding; and
a fourth transmitter winding wound around a direction including first and second electrodes, wherein the direction of the fourth transmitter winding is aligned with the direction of the second receiver winding;
wherein a fifth voltage and the first voltage are in phase:
wherein the fifth voltage is inducted by the third transmitter winding between the first and the second electrode of the first receiver winding when a third driving current flows through the third transmitter winding from its first electrode to its second electrode;
wherein a sixth voltage and the fourth voltage are in phase:
wherein the sixth voltage is inducted by the fourth transmitter winding between the first and the second electrode of the second receiver winding when a fourth driving current flows through the fourth transmitter winding from its first electrode to its second electrode;
wherein the third transmitter winding and the first transmitter winding are coupled in series or in parallel so that, in use, the third driving current flowing through the third transmitter winding and the first driving current flowing through the first transmitter winding are in phase; and
wherein the fourth transmitter winding and the second transmitter are coupled in series or in parallel so that, in use, the fourth driving current flowing through the fourth transmitter winding and the second driving current flowing through the second transmitter winding are in phase.

15. The high-voltage switch of claim 13, further comprising:
a third receiver module including a third power switch and a third receiver winding wound around a direction, the third power switch having control electrodes for selectively driving current flow between power electrodes, the third receiver winding having first and second electrodes, wherein the first and second electrodes of the third receiver winding are connected to the control electrodes of the third power switch;
wherein the direction of the third receiver winding is aligned with the direction of the first transmitter winding; and
a fourth receiver module including a fourth power switch and a fourth receiver winding wound around a direction, the fourth power switch having control electrodes for selectively driving current flow between power electrodes, the fourth receiver winding having first and second electrodes, wherein the first and second control electrodes of the fourth receiver winding are connected to the control electrodes of the fourth power switch;
wherein the direction of the fourth receiver winding is aligned with the direction of the second transmitter winding;
wherein the third receiver winding is located relative to the first transmitter winding and the second transmitter winding so that a fifth voltage and a sixth voltage are in phase opposition:
wherein the fifth voltage is inducted by the first transmitter winding between the first and the second electrode of the third receiver winding when the first driving current flows through the first transmitter winding from its first electrode to its second electrode,
wherein the sixth voltage is inducted by the second transmitter winding between the first and the second electrode of the third receiver winding when the second driving current flows through the second transmitter winding from its first electrode to its second electrode;
wherein the fourth receiver winding is further located relative to the first transmitter winding and the second transmitter winding so that a seventh voltage and the first voltage, are in phase opposition, and an eighth voltage and the second voltage are in phase opposition:
wherein the seventh voltage is inducted by the first transmitter winding between the first and the second electrode of the fourth receiver winding when the first driving current flows through the first transmitter winding from its first electrode to its second electrode,
wherein the eighth voltage is inducted by the second transmitter winding between the first and the second electrode of the second receiver winding when the second driving current flows through the second transmitter winding from its first electrode to its second electrode.

16. A high-voltage switch, comprising:
a first plurality of receiver modules each including a corresponding one of a first plurality of power switches and a corresponding one of a first plurality of receiver windings wound around corresponding directions, each of the first plurality power switches having control electrodes for selectively driving current flow between power electrodes, each of the first plurality of receiver windings having first and second electrodes, wherein the first and second electrodes of each one of the first plurality of the receiver windings are connected to the control electrodes of a corresponding one of the first plurality of power switches;
a second plurality of receiver modules each including a corresponding one of a second plurality of power switches and a corresponding one of a second plurality of receiver windings wound around corresponding directions, each of the second plurality power switches having control electrodes for selectively driving current flow between power electrodes, each of the second plurality of receiver windings having first and second electrodes, wherein the first and second control electrodes of each of the second plurality of receiver windings are connected to the control electrodes of a corresponding one of the second plurality of power switches;
wherein the power electrodes of the first plurality of power switches the power electrodes of the second plurality of power switches are daisy-chained; and
wherein the wireless control includes:
a first plurality of transmitter windings wound around corresponding directions, each of the first plurality of transmitter windings including first and second electrodes;
a second plurality of transmitter windings wound around corresponding directions, each of the first plurality of transmitter windings including first and second electrodes, wherein a center of each of the second plurality transmitter windings is located away from centers of each of the first plurality of transmitter windings and sideways from the directions of each of the first plurality of transmitter windings;
wherein any one of the first plurality of receiver windings is located relative to the first plurality of transmitter windings and the second plurality of transmitter windings so that a first voltage and a second voltage are in phase opposition:
wherein the first voltage is inducted by at least one of the first plurality of transmitter windings between the first and the second electrode of the any one of the first plurality receiver windings when a first driving current flows through the at least one of the first plurality of transmitter windings from its first electrode to its second electrode,
wherein the second voltage is inducted by at least one of the second plurality of transmitter windings between the first and the second electrode of the any one of the first plurality of receiver windings when a second driving current flows through the at least one of the second plurality of transmitter windings from its first electrode to its second electrode;
wherein the first driving current and the second driving current are in phase;
wherein a center of each of the second plurality receiver windings is located away from centers of each one of the first plurality of receiver windings and sideways from the directions of each of the first plurality of receiver windings,
wherein at least one of the second plurality of receiver windings is located relative to the first plurality of transmitter windings and the second plurality of transmitter windings so that a third voltage and the first voltage are in phase opposition, and a fourth voltage and the second voltage are in phase opposition:
wherein the third voltage is inducted by the at least one of the first plurality of transmitter windings between the first and the second electrode of the any of the plurality of second receiver windings when the first driving current flows through the at least one of the first transmitter winding from its first electrode to its second electrode,
wherein the fourth voltage is inducted by the at least one of the second plurality of transmitter windings between the first and the second electrode of the any one of the second plurality of receiver windings when the second driving current flows through the at least one of second plurality of transmitter windings from its first electrode to its second electrode,
wherein the at least one of the first plurality of transmitter windings and the at least one of the second plurality of transmitter windings are coupled in series or in parallel so that, in use, the first driving current flowing through the at least one of first transmitter winding and the second driving current flowing through the second transmitter winding are in phase opposition.

17. The high-voltage switch of claim 16, wherein
each of the first plurality of transmitter windings is printed on a transmitter circuit board;
each of the second plurality of transmitter windings is printed on the transmitter circuit board;
each of the first plurality of receiver windings is printed on a receiver circuit board; and
each of the second receiver windings is printed on the receiver circuit board.

18. The high-voltage switch of claim 17, wherein the receiver circuit board is coupled to the transmitter circuit board so that the receiver circuit board is parallel to the transmitter circuit board.

19. The high-voltage switch of claim 17, wherein
the first plurality of transmitter windings is arranged in a checkerboard pattern about the transmitter circuit board;
each of the second plurality of transmitter windings is located between two adjacent transmitter windings of the first plurality of transmitter windings and in a line or a column of the checkerboard pattern;
the first plurality of receiver windings is arranged in another checkerboard pattern about the receiver circuit board; and
each of the second plurality of receiver windings is located between two adjacent receiver windings of the first plurality of receiver windings and in a line or a column of the other checkerboard pattern.
